(19) United States
(12) Patent Application Publication
(10) Pub. No.: US 2018/0238969 A1
(43) Pub. Date: Aug. 23, 2018

(54) METHOD FOR DETECTING POWER FADE LEVEL OF BATTERY

(71) Applicant: Bordrin Motor Corporation, Southfield, MI (US)

(72) Inventors: Yonghua Li, Ann Arbor, MI (US); Zhiwei Zhang, Shanghai (CN)

(21) Appl. No.: 15/439,379

(22) Filed: Feb. 22, 2017

(51) Int. Cl. G01R 31/36; H01M 10/48

(52) U.S. Cl. CPC G01R 31/3662; H01M 2220/20; G01R 31/3648; H01M 10/486

(57) ABSTRACT

A method for measurement based estimation of a power fade level of a battery determines the power fade level by estimating a series of Ohmic resistance value of the battery based on processing noisy battery parameters measured while the battery is in operation using a battery model and a filtering and estimation algorithm such as Kalman filter. The disclosed method provides an online and accurate estimation of the power fade level of the battery despite the presence of large measurement noises.

### BACKGROUND

### 1. Field of the Invention

The present invention relates to the field of electric vehicle batteries, and more particularly to a method for detecting a power fade level of a battery of an electric vehicle

### 2. Description of Related Art

Numerous high-voltage electric components are provided in an electric vehicle, including, for example, a high-voltage battery pack, a high-voltage cable distribution box, an electric motor controller, an air conditioner controller, a DC/DC converter, a charger, with the battery pack and the battery or batteries therein being one of the most critical components. The performance of a battery usually degrades with use and the elapse of time for use and storage. Such a degradation manifests in two forms: the capacity of the battery changes (decreases), and a charging and discharging power capability changes (decreases) at a same energy-storage level and a same temperature (power fade). As generally recognized by the industry, a loss of capacity of a battery of more than 20% indicates that the battery no longer has sufficient capacity and reached its end of life.

A manifestation of power fade of a battery usually includes an increase in the Ohmic resistance of the battery. In the industry, there is no unified specification as to the relationship between the battery Ohmic resistance and power fade. However, generally, the increase in the Ohmic resistance is inversely proportional to the charging and discharging power at a same temperature and charge amount. It is generally recognized that a level of power loss and fade can be determined by comparing the Ohmic resistance at the begin-of-life (BOL) and the current Ohmic resistance for the battery.

Existing method for determining power fade based on single point measurement of battery parameters has two problems. First, battery Ohmic resistance is closely related to temperature, and usually the measured temperature is only temperature of an entire module rather than temperature on the core of the battery. Therefore, the existing method has relatively high imprecision of detection of battery temperature and the detected temperature at the same time is susceptible to other noises. Second, for online (when the battery is in operation) detection of a battery power fade, it is very difficult to ensure that an Ohmic resistance estimation at a single time point is necessarily precise. Therefore, there is a significant limitation on precision in estimating the power fade level of a battery when an Ohmic resistance estimation value at a single time point is used.

### SUMMARY

The present disclosure provides a method for detecting a power fade level of a battery to deal with the foregoing problems.

In one implementation, a method for detecting a power fade level of a battery pack (or battery cell) maybe employed in an electric vehicle The method may include the following steps:

initializing an index j to 1;

repeating successively the following steps until j is larger than a predetermined index N;
a) monitoring a temperature (in Kelvin, for example) and an uninterrupted working duration of the battery pack until determining at time tⱼ that the monitored temperature and uninterrupted working duration respectively are within a predetermined temperature range and an operation duration range;
b) estimating Ohmic resistance Rⱼ of the battery pack at time tⱼ;
c) based on the Ohmic resistance Rⱼ estimated in step 2), calculating and storing a battery Ohmic resistance factor βⱼ at time tⱼ; and
d) Incrementing j;

determining a least mean square Ohmic resistance factor β for the battery pack from the stored series of Ohmic resistance factors βⱼ;

determining a battery power fade evaluator ε based on the least mean square Ohmic resistance factor β, and

estimating battery power fade level based on the battery power fade evaluator ε.

In one implementation, the step of estimating the Ohmic resistance Rⱼ of the battery pack at time tⱼ comprises:
11) recording voltage uⱼ, current iⱼ, and temperature τⱼ of the battery pack at time tⱼ; and
12) estimating the Ohmic resistance Rⱼ of the battery pack at time tⱼ based on the measured voltage uⱼ, current iⱼ, and temperature τⱼ of the battery pack at time tⱼ.

In one implementation, of the battery power fade detection method above, the step of estimating Ohmic resistance Rⱼ of the battery pack at time tⱼ may be based on Kalman filtering or a least square estimation method.

In one implementation of the power fade detection method above, the step of calculating the battery Ohmic resistance factor βⱼ at time tⱼ may include calculating βⱼ according to:

$${β}_{j} = {τ}_{j} \times ln ( \frac{{R}_{j}}{{R}_{abs}} )$$

where τⱼ is a battery temperature at time tⱼ and R_{abs} is a begin-of-life (BOL) Ohmic resistance reference value of the battery pack

In one implementation of the battery power fade detection method above, the step of determining the least mean square Ohmic resistance factor β includes determining β based on:

$$β = \sqrt{\frac{1}{N} \times ( {\sum }_{j = 1}^{N} {β}_{j}^{2} )} .$$

In one implementation, the number N above is between 100 and 2000.

In one implementation of battery power fade detection method above, the step of determining the battery power fade evaluator ε may include calculating ε based on:

$$ɛ = \frac{β}{{β}_{0}}$$

where β₀ is Ohmic resistance factor of the battery back at a begin-of-life of the battery pack.

In one further implementation of the battery power fade detection method above, the step of estimating battery power fade level based on the battery power fade evaluator ε may include:

61) determining whether the battery power fade evaluator ε is larger than a first predetermined evaluator threshold (CAL3) and determining that the battery pack is at an end of its life upon determining that the battery power fade evaluator ε is larger than the first predetermined evaluator; and upon determining that the battery power fade evaluator ε is not larger than the first predetermined evaluator, entering Step 62);

62) determining whether the battery power fade evaluator ε is between the first predetermined evaluator threshold and a second evaluator threshold (CRL2) and determining that the battery pack is in a limited-power operation mode upon determining that the battery power fade evaluator ε is between the first predetermined evaluator threshold and the second evaluator threshold; and entering Step 63) otherwise; and

63) determining whether the battery power fade evaluator ε is smaller than a third predetermined evaluator threshold (CAL1) and determining that a power fade has not occurred to the battery pack upon determining that the battery evaluator ε is smaller than the third predetermined evaluator.

In one implementation, the predetermined temperature range may be between 15° C. and 30° C., or 288.15° Kelvin to 303.15° Kelvin.

In one implementation, the predetermined operation duration range may be 24 hours.

In one implementation of the battery power fade detection method above, the battery pack is installed in an electric vehicle and the uninterrupted working duration of the battery pack comprises a duration between a key-on operation followed by a key-off operation of the electric vehicle.

In another implementation of battery power fade detection method above, the battery pack is installed in an electric vehicle and wherein step 1) to 4) above are performed online.

Compared with the prior art, the present invention has the following beneficial effects. First, compared with a method for determining a power fade level of a battery through direct comparison of Ohmic resistance values, in this method, an Ohmic resistance factor β is used as an indication for a power fade level. Because the Ohmic resistance factor β is a parameter unrelated to temperature, in this method, impact of measurement errors or noises in voltage, current, and particularly in temperature can be effectively reduced.

Second, an Ohmic resistance value and temperature are combined to estimate and calculate each Ohmic resistance factor, and a least mean square error of a series of multiple Ohmic resistance factors is calculated leading to much less dependence of the estimated Ohmic resistance factor on the precision of detection of temperature. In addition, a least mean square error rather than an average value is chosen for calculation of an Ohmic resistance factor, so that the precision of a Ohmic resistance factor is further improved.

Third, a fade level evaluator is obtained according to the comparison between a least mean square Ohmic resistance factor and an Ohmic resistance factor value of a battery at the BOL, providing a simple, direct, intuitive, and normalized representation the power fade level of the battery pack.

Fourth, three threshold values CAL1, CAL2 and CRL3 of the fade evaluator, respectively representing a power fade alarm value, a limited power operation indication value, and a life termination value, are predetermined for classifying the power fade status of the battery pack. As such, the power fade level of the battery pack is intuitively qualified, providing a simple guidance as to whether and when to replace a battery pack.

Fifth, an Ohmic resistance value of the battery is detected only in an effective range of battery temperature and operation duration, e.g., the temperature between 15° C. and 30° C., and an operation duration of, e.g., no longer than 24 hours. Such detection ensures minimal impact of temperature measurement on Ohmic resistance value of a battery. Moreover, a working time of the battery may be set such it does not exceed one day. As such, error caused by aging of the battery during the current round of Ohmic resistance factor calculation is reduced as much as possible.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a flowchart of a method for detecting a power fade level of a battery;

FIG. 2 is an equivalent circuit diagram of a battery;

FIG. 3 shows exemplary change of a battery power fade factor with time;

FIG. 4 shows the temperature of a battery as a function of time; and

FIG. 5 illustrates estimated Ohmic resistance value of a battery as a function of temperature.

### DETAILED DESCRIPTION

The present invention is described below in detail with reference to the accompanying drawings and specific embodiments. These embodiments are implemented based on the technical solution of the present invention, and detailed implementation manners and specific operation processes are provided below. However, the protective scope of the present invention is not limited to the following embodiments.

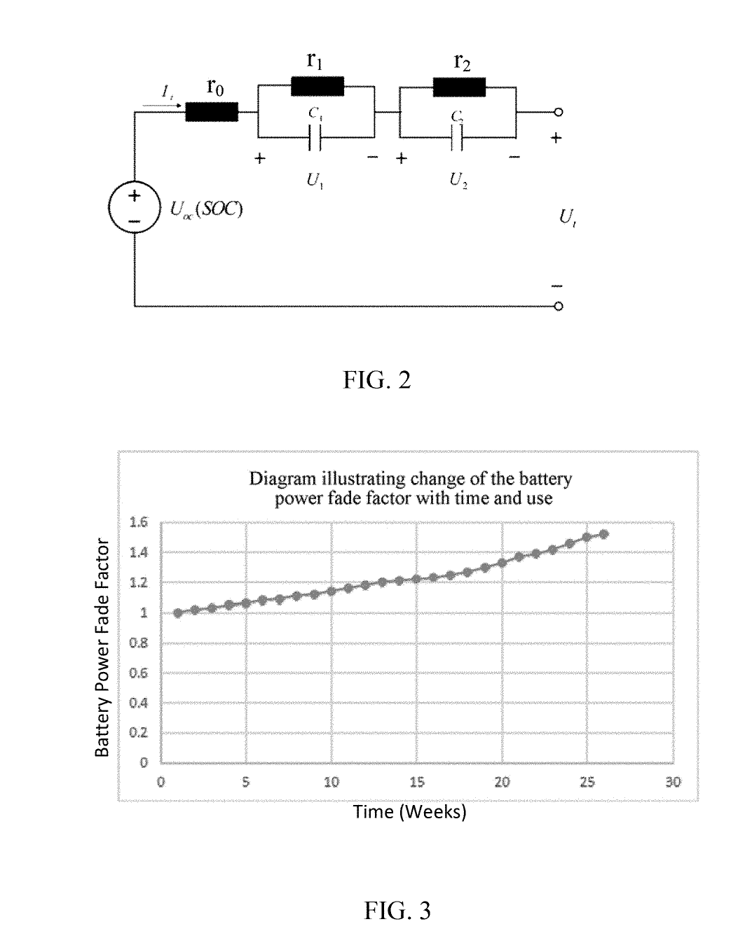

FIG. 2 shows an equivalent circuit diagram of a battery pack or a battery cell. The non-limiting term battery will be used hereinafter to denote either a battery pack or a battery cell. The disclosure below applies to either a battery pack or a battery cell. Resistor r₀ represents the Ohmic resistance caused by the accumulation and dissipation of charges in an electric double layer of the battery (e.g., a lithium-ion battery). Resistors r1 and c1 are activation polarization resistances and capacitances. Resistors r2 and c2 are concentration polarization resistances and capacitances. This battery model provides an equivalent ohmic resistance R for the battery. A general battery power process satisfies an Arrehenius equation: when temperature is higher, an electrochemical process in a battery becomes faster, and corresponding Ohmic resistance R becomes lower. There are various models for describing the relationship between the battery temperature and the Ohmic resistance of the battery. In one exemplary model, regardless of a degree at which the battery is used, an exponential relationship may be maintained between the Ohmic resistance of the battery and temperature:

R=R_{abs}×e^{β/τ} (1)

where R_{abs} is a constant reference value, τ is temperature of a battery (unit: Kelvin), β is a factor that determines the Ohmic resistance (referred to as the Ohmic resistance factor hereinafter). Power fade of a battery is directly related to the increase of the battery Ohmic resistance R and is thus reflected in an increase in this Ohmic resistance factor. Other models having a temperature invariant parameter for representing the Ohmic resistance of the battery, similar to the β factor above may be used. Once R is estimated, the invariant parameter may be back calculated based on the model as a measure of the Ohmic resistance of the battery. The model underlying formula (1) is merely an example. The disclosure below is not limited to this particular model.

All existing technologies and methods for estimating the power fade are based on FIG. 2 or a similar battery model, in which a model parameter such as the battery Ohmic resistance R is estimated according to a terminal voltage (referred to as Open Circuit Voltage, or OCV) of a battery and by using current, and module temperature. Existing methods typically rely on single point measurement of these parameters. For example, a single voltage, current and other parameters may be measured, from which a battery Ohmic resistance may be estimated. From the estimated battery Ohmic resistance and a measured temperature, β may be calculated as a representation of power fade.

However, single point measurement is noisy and inaccurate, particularly for an online measurement where the battery and electric vehicle is in operation. As such, it may be advantageous to employ filtering and estimation techniques such as a Kalman filtering method and the least square method for removing noise from the measurements and for correcting noisy measurements with predictions using a series of measurements rather than a single point measurement. As described in more detail below, battery Ohmic resistance and Ohmic resistance factor β determined in such way may be more precise in spite of online measurements that are noisy in nature.

From Formula (1), it can be seen that for the same temperature, change of Ohmic resistance R of a battery depends on change of the Ohmic resistance factory β. β is a parameter unrelated to temperature. Therefore, if β can be estimated online precisely and reliably, change of Ohmic resistance R of the battery can be obtained accordingly, so that a power fade level of the battery is determined.

The Ohmic resistance factor β cannot be directly measured. However, through measurement of current, voltage, and temperature of a battery, and by using a predetermined battery model, such as the model of FIG. 2, parameters of the battery model such as the battery Ohmic resistance R can be estimated online. These parameters estimated in each individual instance may not be highly precise. In addition, because of a level of excitation of a battery input parameter (current) on the battery, an estimated value at a particular time or in a particular single instance may not be necessarily very reliable. However, if a series of measurements are made during operation of a battery over time, a series of values of Ohmic resistance factors may be estimated in batches using a noise filtering algorithm based on this series of noisy measurements.

Without loss of generality, it is assumed that R_{abs} in Formula (1) is known at the BOL. During each time period when a battery is used (for example, between each Keyon/Keyoff trip of an electric vehicle), the Kalman filtering method or another parameter estimation method may be used to estimate a series of N Ohmic resistance parameters based on noise measurements at different times tⱼ. These estimated Ohmic resistance values are associated with R_{abs}, Ohmic resistance factor β, and temperature r such that

$$\begin{matrix}{R}_{1} = {R}_{abs} \times {e}^{{β}_{1} / {τ}_{1}} \\ {R}_{2} = {R}_{abs} \times {e}^{{β}_{2} / {τ}_{2}} \\ {R}_{3} = {R}_{abs} \times {e}^{{β}_{3} / {τ}_{3}} \\ ⋮ \\ {R}_{N} = {R}_{abs} \times {e}^{{β}_{N} / {τ}_{N}}\end{matrix} \qquad ( 2 )$$

In Formula (2), Rⱼ is Ohmic resistance values of R that is obtained based on the battery model using the Kalman filtering method or another parameter estimation method on the series of measurements (voltages, current, etc.). Kalman filtering, for example, explores the correlation between the series of measurements of battery parameters and uses weighted combination of actual measurements of the parameters (which are noisy) and statistical predictions of the parameters as the estimated values for the parameters to effectively reduce noises. R_{abs} is a known constant reference value, τⱼ is a temperature value of a battery during estimation of Rⱼ, and the Ohmic resistance factor βⱼ is a value that is to be obtained and its change represents actual change of Ohmic resistance of the battery as its power delivering or accepting capability fades as it ages, and is unrelated to temperature. If Formula (2) is reversed to perform calculation, for the series of tⱼ during the time period (for example, between a keyon/keyoff trip):

$$\begin{matrix}{β}_{1} = {τ}_{1} \times ln ( \frac{{R}_{1}}{{R}_{abs}} ) \\ {β}_{2} = {τ}_{2} \times ln ( \frac{{R}_{2}}{{R}_{abs}} ) \\ {β}_{3} = {τ}_{3} \times ln ( \frac{{R}_{3}}{{R}_{abs}} ) \\ ⋮ \\ {β}_{N} = {τ}_{n} \times ln ( \frac{{R}_{1}}{{R}_{abs}} )\end{matrix} \qquad ( 3 )$$

an eventual factor β may be obtained by using a least mean square error:

$$β = \sqrt{\frac{1}{N} \times ( {\sum }_{j = 1}^{N} {β}_{j}^{2} )} \qquad ( 4 )$$

The factor β obtained as above represents value of Ohmic resistance of R a battery during a current Keyon/Keyoff trip. β should be temperature independent even though the method above relies on temperature measurements. Noise in temperature measurements at each time tⱼ does affect estimation of Ohmic resistance R for that time. However, the estimated factor β above based on multiple measurement values at N times by taking least mean square error of βⱼ becomes much less dependent on the precision of temperature detection.

Once a particular number of estimates (e.g., N) is reached in the estimation of the Ohmic resistance R in a current Keyon/Keyoff trip, a corresponding factor β may be calculated by using Formula (4). On such a basis, a factor β calculated by using Formula (4) may be compared with a factor β₀ of the battery at the BOL to obtain a normalized β. One or more diagnosis values for normalized β may be pre-determined before the battery is put in use. According to the one or more diagnostic normalized β values, a battery management system may precisely provide a power fade level of a battery, and provide a decision regarding whether a battery can still be used.

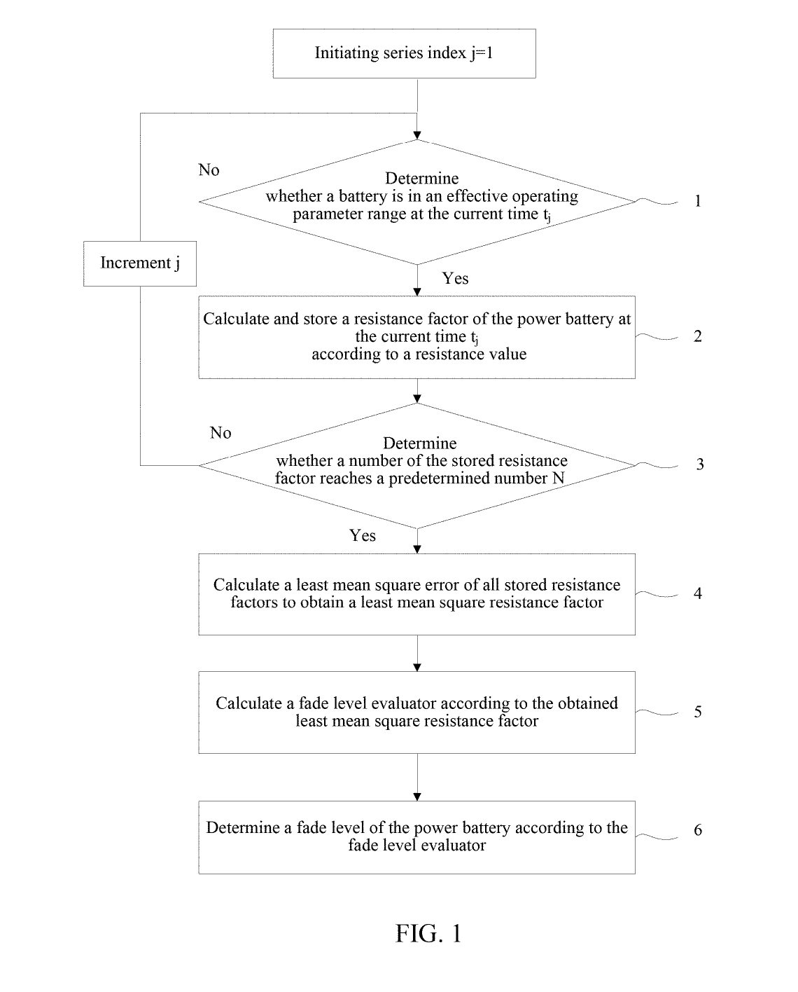

According to the foregoing method, as shown in FIG. 1, this embodiment provides a method for detecting a power fade level of a battery. The method include making a series of estimates of battery Ohmic resistance R at different time tⱼ for a predetermined number of N times, each estimated battery Ohmic resistance value is represented by R (j=1, . . . , N). Specifically, the following steps may be performed:

1) Determine whether a battery is in an effective range at the current time (that is, the battery is in the temperature threshold range and that a time tⱼ corresponding to detecting/estimating an Ohmic resistance value Rⱼ of the battery is in a time threshold range. for example, the temperature range for the battery may be between 15° C. and 30° C., and tⱼ does not exceed 24 hours relative to the beginning of the series of measurements such as t₁), and if yes, detect/estimate the Ohmic resistance value Rⱼ of the battery at the current time tⱼ, or if not, return to continue with the determining step above, where a specific process of detecting/estimating the Ohmic resistance value of the battery Rⱼ at the current time tⱼ includes:

11) measuring and recording a voltage value uⱼ, a current value iⱼ, and the temperature τⱼ of the battery at the current time tₖ; and

12) performing recursion according to the voltage value uⱼ, the current value iⱼ, and the temperature τⱼ that are obtained in Step 11) and by using a parameter estimation and noise reduction method, to obtain the estimated Ohmic resistance value Rⱼ of the battery at the current time

2) Calculate and store an Ohmic resistance factor βⱼ of the battery at the current time tⱼ according to the Ohmic resistance value Rⱼ that is obtained in Step 1) according to:

$${β}_{j} = {τ}_{j} \times ln ( \frac{{R}_{j}}{{R}_{abs}} )$$

where τⱼ is the temperature of the battery at the current time tⱼ, and R_{abs} is an Ohmic resistance reference value of the battery at the BOL.

3) Determine whether the stored number of Ohmic resistance factors reaches a predetermined number N (e.g., 100 to 2000), and if yes, enter Step 4), or if not, increment j and return to Step 1).

4) Calculate a least mean square error of all stored Ohmic resistance factors βⱼ obtained by repeating steps 1) to 3) to yield a least mean square Ohmic resistance factor β:

$$β = \sqrt{\frac{1}{N} \times ( {\sum }_{j = 1}^{N} {β}_{j}^{2} )}$$

where N again, is a total quantity or number of stored Ohmic resistance factors βⱼ of the battery.

5) Calculate a power fade level evaluator ε according to the obtained least mean square Ohmic resistance factor β, which is specifically:

$$ɛ = \frac{β}{{β}_{0}}$$

where β₀ is an Ohmic resistance factor value of the battery at the BOL.

6) Determine a power fade level of the battery according to the fade level evaluator ε:

61) determining whether a power fade evaluator ε is greater than a life termination value CAL3, and if yes, indicating that the life of the battery is effectively ended, or if not, entering Step 62);

62) determining whether the power fade evaluator ε is greater than a limited power operation calibration value CRL2, and if yes, indicating that the battery is in a limited power running state, or if not, entering Step 63); and

63) determining whether the power fade evaluator ε is greater than a power fade alarm value CAL1, and if yes, indicating that power fade of the battery already occurs, or if not, indicating that power fade of the battery has not occurred yet, and returning to Step 61).

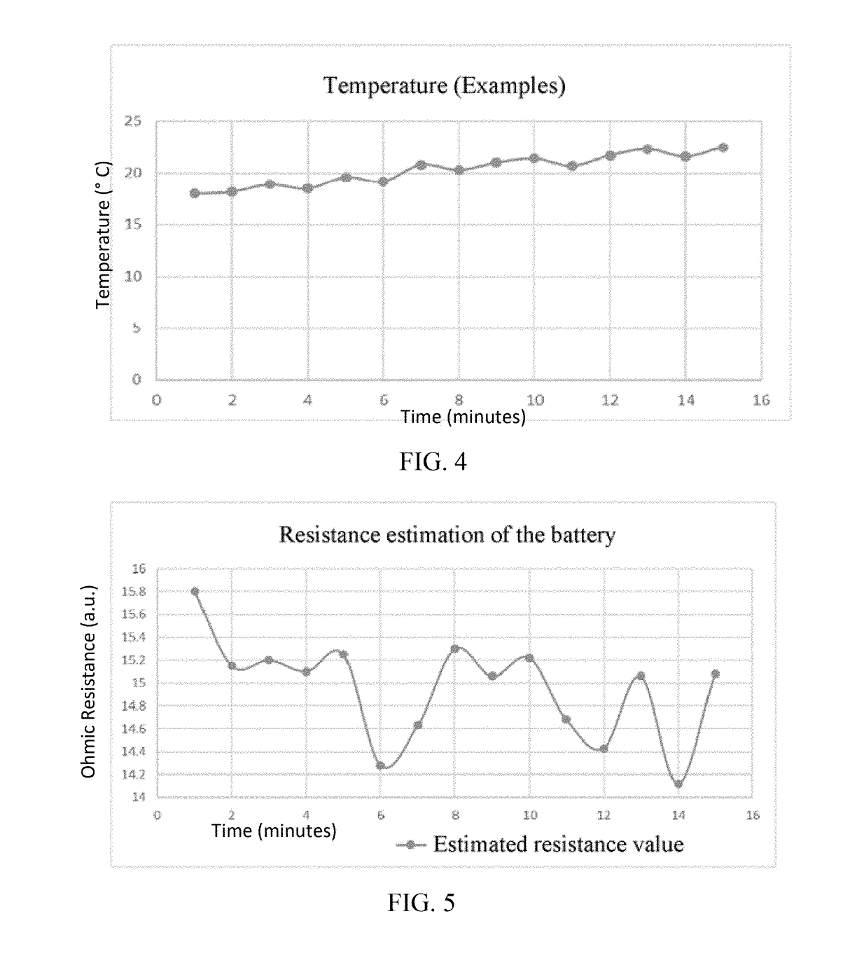

Detection is performed according to the foregoing method to obtain a group of sampling data, as shown in FIG. 3 to FIG. 5. As can be seen from FIG. 3 to FIG. 5, no matter one point or an average of two multiple points is used, it is difficult to cure the defect in direct use of an Ohmic resistance value. The consideration of a factor β can very effectively reduce the impact of the imprecision of measurement of temperature, voltage, and current and estimation of Ohmic resistance.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

Further the methods described herein may be embodied in a computer-readable medium. The term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

As a person skilled in the art will readily appreciate, the above description is meant as an illustration of the principles of this invention. This description is not intended to limit the scope or application of this invention in that the invention is susceptible to modification, variation and change, without departing from spirit of this invention, as defined in the following claims.

1. A battery power fade detection method executed by a circuit for a battery pack, the circuit being configured to measure a temperature of the battery pack, the method comprising the steps of:
initializing an index j to 1;
repeating successively steps a) to d) until j is larger than a predetermined index N;
a) Monitoring by the circuit a temperature and an uninterrupted working duration of the battery pack until determining at time tⱼ that the monitored temperature and uninterrupted working duration respectively are within a predetermined temperature range and an operation duration range;
b) estimating by the circuit Ohmic resistance Rⱼ of the battery pack at time tⱼ;
c) based on the Ohmic resistance Rⱼ estimated in step 2), calculating and storing by the circuit a battery Ohmic resistance factor βⱼ at time tⱼ; and
d) Incrementing j;
determining by the circuit a least mean square Ohmic resistance factor β for the battery pack from the stored Ohmic resistance factors βⱼ;
determining by the circuit a battery power fade evaluator ε based on the least mean square Ohmic resistance factor β; and
estimating by the circuit battery power fade level based on the battery power fade evaluator ε.

2. The battery power fade detection method according to claim 1, wherein estimating the Ohmic resistance R; of the battery pack at time tⱼ comprises:
measuring and recording voltage uⱼ, current iⱼ, and temperature τⱼ of the battery pack at time at time tⱼ; and
estimating the Ohmic resistance Rⱼ of the battery pack at time tⱼ based on measured voltage uⱼ, current iⱼ, and temperature τⱼ of the battery pack at time tⱼ.

3. The battery power fade detection method according to claim 2, wherein estimating Ohmic resistance Rⱼ of the battery pack at time tⱼ is based on Kalman filtering or a least square estimation method.

4. The battery power fade detection method, according to claim 1, wherein calculating the battery Ohmic resistance factor βⱼ at time tⱼ comprises:
calculating βⱼ according to:
$${β}_{j} = {τ}_{j} \times ln ( \frac{{R}_{j}}{{R}_{abs}} ) ;$$
and
wherein τⱼ a battery temperature at time tⱼ and R_{abs} is a begin-of-life Ohmic resistance reference value of the battery pack corresponding to τⱼ.

5. The battery power fade detection method according to claim 1, wherein determining the least mean square Ohmic resistance factor β comprises determining β based on:
$$β = \sqrt{\frac{1}{N} \times ( {\sum }_{j = 1}^{N} {β}_{j}^{2} )} .$$

6. The battery power fade detection method according to claim 1, wherein N is between 100˜2000.

7. The battery power fade detection method according to claim 1, wherein determining the battery power fade evaluator ε comprising calculating ε based on:
$$ɛ = \frac{β}{{β}_{0}} ,$$
wherein β₀ is an Ohmic resistance factor of the battery back at a begin-of-life of the battery pack.

8. The battery power fade detection method according to claim 1, wherein estimating battery power fade level based on the battery power fade evaluator ε comprises the steps of:
determining whether the battery power fade evaluator ε is larger than a first predetermined evaluator threshold and determining that the battery pack is at an end of its life upon determining that the battery power fade evaluator ε is larger than the first predetermined evaluator;
determining whether the battery power fade evaluator ε is between the first predetermined evaluator threshold and a second evaluator threshold, and determining that the battery pack is in a limited-power operation mode upon determining that the battery power fade evaluator ε is between the first predetermined evaluator threshold and the second evaluator threshold; and
determining whether the battery power fade evaluator ε is smaller than a third predetermined evaluator threshold and determining that a power fade has not occurred to the battery pack upon determining that the battery the battery evaluator ε is smaller than the third predetermined evaluator.

9. The battery power fade detection method, according to claim 1, wherein the predetermined temperature range comprises a temperature range of 15˜30° C.

10. The battery power fade detection method according to claim 1, wherein the predetermined operation duration range comprises 24 hours.

11. The battery power fade detection method according to claim 1, wherein the battery pack is installed in an electric vehicle and the uninterrupted working duration of the battery pack comprises a duration between a key-on operation followed by a key-off operation of the electric vehicle.

12. The battery power fade detection method according to claim 1, wherein the battery pack is installed in an electric vehicle and wherein step 1) to 4) are performed online.

13. A system for detecting battery power fade detection for a battery pack, comprising:
a circuit in communication with the battery pack, the circuit configured to monitor a temperature of the battery pack;
wherein the circuit is configured to:
initialize an index j to 1;
repeat successively steps a) to d) until j is larger than a predetermined index N;
a. monitor a temperature and an uninterrupted working duration of the battery pack until determining at time tⱼ that the monitored temperature and uninterrupted working duration respectively are within a predetermined temperature range and an operation duration range;
b. estimate Ohmic resistance Rⱼ of the battery pack at time tⱼ;
c. based on the Ohmic resistance Rⱼ estimated in step 2), calculate and storing a battery Ohmic resistance factor βⱼ at time tⱼ; and
d. Increment j;
determine a least mean square Ohmic resistance factor β for the battery pack from the stored Ohmic resistance factors βⱼ;
determine a battery power fade evaluator ε based on the least mean square Ohmic resistance factor β; and
estimate battery power fade level based on the battery power fade evaluator ε.

14. The system according to claim 13, wherein the circuit is further configured to:
measure and record voltage uⱼ, current iⱼ, and temperature τⱼ of the battery pack at time at time tⱼ; and
estimate the Ohmic resistance Rⱼ of the battery pack at time tⱼ based on measured voltage uⱼ, current iⱼ, and temperature τⱼ of the battery pack at time tⱼ.

15. The system according to claim 14, wherein estimating Ohmic resistance Rⱼ of the battery pack at time tⱼ is based on Kalman filtering or a least square estimation method.

16. The system according to claim 13, wherein the circuit is further configured to calculate the battery Ohmic resistance factor βⱼ at time tⱼ by:
calculate βⱼ according to:
$${β}_{j} = {τ}_{j} \times ln ( \frac{{R}_{j}}{{R}_{abs}} ) ;$$
and
wherein τⱼ a battery temperature at time tⱼ and R_{abs} is a begin-of-life Ohmic resistance reference value of the battery pack corresponding to τⱼ.

17. The system according to claim 13, wherein determining by the circuit the least mean square Ohmic resistance factor β comprises determining β based on:
$$β = \sqrt{\frac{1}{N} \times ( {\sum }_{j = 1}^{N} {β}_{j}^{2} )} .$$

18. The system according to claim 13, wherein N is between 100˜2000.

19. The system according to claim 13, wherein determining by the circuit the battery power fade evaluator ε comprising calculating ε based on:
$$ɛ = \frac{β}{{β}_{0}} ,$$
wherein β₀ is an Ohmic resistance factor of the battery back at a begin-of-life of the battery pack.

20. The system according to claim 13, wherein estimating by the circuit the battery power fade level based on the battery power fade evaluator ε comprises:
determine by the circuit whether the battery power fade evaluator ε is larger than a first predetermined evaluator threshold and determining that the battery pack is at an end of its life upon determining that the battery power fade evaluator ε is larger than the first predetermined evaluator;
determine by the circuit whether the battery power fade evaluator ε is between the first predetermined evaluator threshold and a second evaluator threshold, and determining that the battery pack is in a limited-power operation mode upon determining that the battery power fade evaluator ε is between the first predetermined evaluator threshold and the second evaluator threshold; and
determine by the circuit whether the battery power fade evaluator ε is smaller than a third predetermined evaluator threshold and determining that a power fade has not occurred to the battery pack upon determining that the battery the battery evaluator ε is smaller than the third predetermined evaluator.

21. The system according to claim 13, wherein the predetermined temperature range comprises a temperature range of 15−30° C.

22. The system of claim 13, wherein the battery pack and the circuit are installed in an electric vehicle and the uninterrupted working duration of the battery pack comprises a duration between a key-on operation followed by a key-off operation of the electric vehicle.
